(19) United States
(12) Patent Application Publication
(10) Pub. No.: US 2006/0003236 A1
(43) Pub. Date: Jan. 5, 2006

(54) Photomask and near-field exposure method

(75) Inventors: Natsuhiko Mizutani, Tokyo (JP); Yasuhisa Inao, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/168,421

(22) Filed: Jun. 29, 2005

(30) Foreign Application Priority Data
Jun. 30, 2004 (JP) 194819/2004(PAT.)

(51) Int. Cl. G03C 5/00; G03F 1/00

(52) U.S. Cl. 430/5; 430/322; 430/394; 430/311

(57) ABSTRACT

Disclosed is a photomask for near-field exposure, that includes a light blocking film having a group of small openings being arrayed and each having an opening width not greater than a wavelength of exposure light, wherein a shape and/or disposition of the small-opening group is set so that near-field light escaping from the small openings in response to projection of exposure light to the small openings has approximately even light intensity distributions.

### FIELD OF THE INVENTION AND RELATED ART

This invention relates to a photomask usable in near-field exposure and specifically for near-field one-shot exposure. In another aspect, the invention concerns a near-field exposure method using such photomask.

Enlarging capacity of semiconductor memories and increasing speed and density of CPUs necessitates further reduction in processing size of optical lithography. Generally, the processing limits of microprocessing based on an optical lithographic apparatus are about the wavelength of a light source. Hence, the wavelength of a light source in optical lithographic apparatuses has been shortened, as by using near ultraviolet radiation laser, for example. Currently, microprocessing of a size of about 0.1 μm is being realized.

Here, in order to perform microprocessing of a size of 0.1 μm or under by use of optical lithographic apparatuses, the wavelength of the light source has to be shortened further, and there are many problems to be solved in relation to such extraordinarily short wavelength region, such as lens development, for example.

Another attempt to enabling microprocessing by use of optical lithographic apparatuses, separate from the movement toward the wavelength shortening, is a near-field exposure method.

U.S. Pat. No. 6,171,730 discloses a method (one-shot exposure method) in which a photomask having a pattern arranged to produce near-field light leaking or escaping from clearances of a light blocking film is closely contacted to a photoresist applied onto a substrate to expose the photoresist, whereby a fine pattern of the photomask as a whole is simultaneously transferred to the photoresist.

However, the aforementioned U.S. patent mentions to nothing about dispersion of intensity distributions of near-field light.

U.S. Pat. No. 5,242,770 discloses uniforming the size of optical images of a dense pattern and an isolated pattern by applying edge intensity leveling bars. However, this technique is inherently to correct a proximity effect of an optical image in the projection exposure, and it can not be directly applied to the near-field mask exposure.

U.S. Pat. No. 6,720,115 discloses near-field exposure method and near-field exposure apparatus wherein the exposure amount is controlled in accordance with the opening density of a mask. However, this patent document does not mention to anything about uniforming intensity distributions of near-field light at plural small openings by controlling the shape and disposition of the small-opening pattern.

### SUMMARY OF THE INVENTION

It is accordingly an object of the present invention to provide a unique and improved photomask by which intensity distribution of near-field light can be corrected appropriately.

It is another object of the present invention to provide a near-field exposure method using such photomask.

In accordance with an aspect of the present invention, there is provided a photomask for near-field exposure, comprising: a light blocking film having a group of small openings being arrayed and each having an opening width not greater than a wavelength of exposure light, wherein a shape and/or disposition of the small-opening group is set so that near-field light escaping from the small openings in response to projection of exposure light to the small openings has approximately even light intensity distributions.

In accordance with another aspect of the present invention, there is provided a near-field exposure method, comprising: preparing a photomask as recited above; bringing the photomask into close contact with a substrate to be exposed, having a photoresist formed thereon; irradiating the photomask with exposure light to produce an optical latent image in the photoresist, wherein, where a correction opening is provided, the amount of exposure light irradiation is determined so that an exposure amount of near-field light at the correction opening becomes small and substantially no image is formed thereby.

Briefly, in accordance with a photomask of the present invention, the shape and disposition of an opening pattern may be specified so as to provide approximately even intensity distributions of near-field light at the small openings.

In accordance with a near-field exposure method of the present invention, a correction opening may be provided so as to provide approximately even intensity distributions of near-field light at the small openings, wherein in such case substantially no image is produced by this correction opening. In other words, such correction opening provides substantially no influence upon the photoresist.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1A is a plan view showing the structure of a known type photomask.

FIG. 1B is a longitudinal section of a know type photomask, being mounted to a support member.

FIG. 2 is a schematic view of a general structure of an exposure apparatus.

FIGS. 3A-3D are schematic views, respectively, for explaining the process of forming a resist pattern in accordance with a dual-layer resist method.

FIG. 4 is a schematic view for explaining a mutually strengthening function of near-field light.

FIG. 5 is a schematic view showing an opening pattern of a photomask according to a first embodiment of the present invention.

FIG. 6 is a schematic view showing an opening pattern of a photomask according to a second embodiment of the present invention.

FIG. 7 is a schematic view showing an opening pattern of a photomask according to a third embodiment of the present invention.

### DESCRIPTION OF THE PREFERRED EMBODIMENTS

Preferred embodiments of the present invention will now be described with reference to the attached drawings. In the drawings, line reference numerals are assigned to similar structural portions or functions, and duplicate description of them is omitted appropriately.

### Embodiment 1

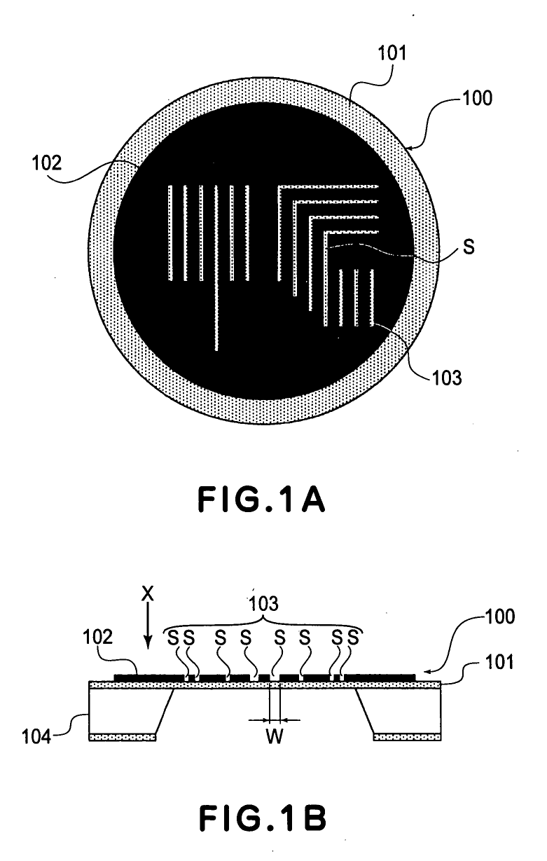

FIGS. 1A and 1B show a known type photomask 100 for a near-field one-shot exposure process. Specifically, FIG. 1A is a plan view of the photomask 100 as viewed from the front surface side (in a direction of an arrow X in FIG. 1B). FIG. 1B is a longitudinal section of the photomask 100 being mounted to a supporting member 104, the section being taken along the thickness direction thereof.

As shown in these drawings, the photomask 100 comprises a mask base material 101 and a light blocking film 102 provided on the mask base material 101 (on the front surface thereof).

The mask base material 101 has a thickness T of 0.1-100 μm, and it is made of a material such as SiN, SiO2 or SiC, for example, having large transmittance with respect to exposure light (to be described later).

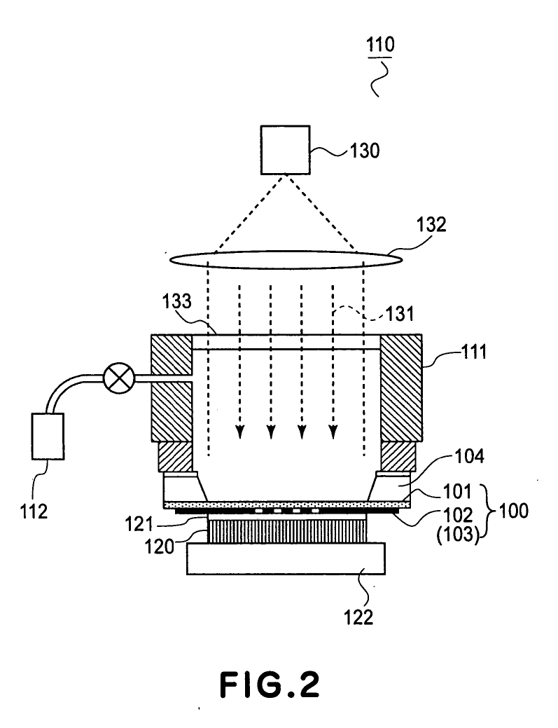

On the other hand, the light blocking film 102 has a thickness t, and it is made of a metal material such as Cr, Al, Au or Ta, for example, having small transmittance with respect to the exposure light. Formed on this light blocking film 102 is an opening pattern (small-opening group) 103 consisting of a plurality of small openings. As best seen in FIG. 1A, each small opening is defined by a slit s of rectangular shape, for example, as viewed from the front surface side. As shown in FIG. 1B, each slit s extends through the light blocking film 102 from its front surface side to its back surface side. The slit s has an opening width w which is made not greater than the wavelength of exposure light to be produced from an exposure light source (Hg lamp 130 in FIG. 2), and the opening length of the slit is made sufficient long as compared with its opening width w. Such opening pattern 103 can be produced in accordance with a direct processing method using a focusing ion beam or a scanning probe processing machine, a lithographic method for processing a resist film on the basis of electron lithography or X-ray lithography, a micropattern forming method based on nanoimprint method or near-field exposure method, for example.

Generally thin-film like photomask 100 as described above is supported by the support member 104. The support member 104 has a structure as shown in FIG. 1B, and it supports the outer peripheral portion of the mask base material 101. The portion of the light blocking film 102 where the opening pattern 103 is formed, corresponds to the void of the supporting member 104.

This photomask 100 is going to be brought into close contact with a thin-film like photoresist applied to a substrate (to be described later) and, by projecting light thereto in a direction perpendicular to it, the pattern is transferred.

More specifically, with the light projected onto the photomask 100, a light intensity distribution provided thereby within the photoresist produces an optical latent image in the photoresist. By performing an appropriate developing process to the photoresist, a photoresist pattern corresponding to this optical latent image is obtainable.

FIG. 2 shows an exposure apparatus for transferring a pattern onto a substrate having a photoresist applied thereto and holding the photomask 100 thereon.

The photomask 100 for near-field exposure is mounted to the bottom of a pressure adjusting container 111 through the supporting member 104 with its front surface facing down, that is, with the mask base material 101 positioned upwardly and the light blocking film 102 positioned downwardly. In other words, the photomask 100 is disposed with its front surface (lower surface as viewed in the drawing) placed outside the pressure adjusting container 111 and with its rear surface (upper surface in the drawing) facing to the pressure adjusting container 111. The inside pressure of the pressure adjusting container 111 can be adjusted by use of pressure adjusting means 112.

As regards an article to be exposed, a substrate 120 having a resist film (photoresist) 121 formed on its surface is used. The substrate 120 is mounted on a stage 122. By moving the stage 308 along an X-Y plane, relative alignment of the substrate 120 with the photomask 100 with respect to two-dimensional directions along the mask surface is carried out. Then, the stage 122 is driven in a direction of a normal to the mask surface (i.e., upward/downward direction as viewed in the drawing), to bring the photomask into intimate contact with the resist film 121 on the substrate 120.

By adjusting the inside pressure of the pressure adjusting container 111 through the pressure adjusting means 112, the surface of the photomask 100 and the resist film 121 on the substrate 120 are brought into close contact with each other so that, throughout the whole surface the clearance between them becomes equal to 100 nm or under.

Thereafter, exposure light 131 emitted from an Hg lamp (exposure light source) 130 and transformed by a collimator lens 132 into parallel light, is introduced into the pressure adjusting container 111 through a glass window 133, such that the exposure light is projected onto the photomask 100 from its back side. In response to this illumination, near field is produced adjacent the slits at the front side of the photomask 100, by which exposure of the resist film 121 is carried out.

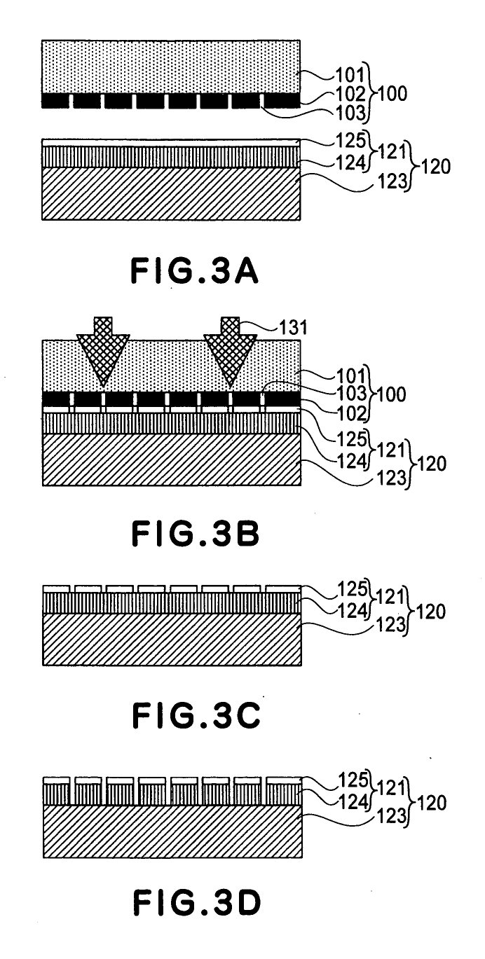

FIGS. 3A-3D illustrate a pattern forming method according to this embodiment, including one buffering layer. This method is called “dual-layer resist method”. FIG. 3A shows a photomask 100 and a substrate 120 which is an object to be exposed. As described hereinbefore, the photomask 100 comprises a mask base material 101 and a light blocking film 102 having an opening pattern 103. The substrate 120 was produced as follows.

First, an Si substrate was coated with a negative type photoresist by using a spin coater. Then, it was hard baked to provide a first layer, that is, a lower layer resist (versatile resist: buffering layer) 124. The lower layer resist 124 had a 180 nm thickness. By this heating process, the photosensitivity of the lower layer resist 124 is gone.

Subsequently, an Si containing positive type resist (e.g., “FH-SP3CL” available from Fuji Film Arch Inc.) was applied onto the lower layer resist 124 and, after that, it was prebaked to provide a second layer, that is, an upper layer resist 125. The upper layer resist 125 had a 20 nm thickness, and a photoresist layer having dual layer structure was produced in this manner.

The Si substrate 123 having a photoresist layer of dual-layer structure and the photomask 100 were approximated to each other by the exposure apparatus 110 shown in FIG. 2 as described, and a pressure was applied to bring the upper layer resist 125 and the photomask 100 into close contact with each other. Then, exposure light 131 was projected through the photomask 100, and the pattern of the photomask 100 was transferred to the upper layer resist 125 (FIG. 3B). After that, the photomask 100 was disengaged from the upper layer resist 125 surface, and development of the upper layer resist 125 as wall as postbake were carried out, whereby the pattern of the photomask 100 was transferred as a resist pattern (FIG. 3C).

However, it was found that, in the resist pattern shown in FIG. 1, the intensity distribution of near-field light at a slit, of plural slits formed on the light blocking film 102, which slit was placed at an end portion, was low.

This problem could be solved by the inventors of the subject application, as follows.

As regards the shape of an optical latent image produced in a thin film photoresist, that is, light intensity distribution, it can be numerically analyzed by using a vector electromagnetic field analysis method.

The inventors have analyzed the shape of this optical latent image in accordance with a finite differential time domain method (FDTD method) which is one of vector electromagnetic field analysis methods.

The calculations were done under the following conditions. The mask base material 101 was made of SiN having a refractive index 1.9, and as the light blocking film 102, a Cr film of a thickness t of 20 nm was formed on the surface of the mask base material 101. Then, an opening pattern 103 consisting of a plurality of slits (small openings) was formed in the light blocking film 102. The photomask 100 thus produced was brought into intimate contact with a photoresist upon an Si substrate. As regards the exposure light source, an Hg lamp 130 (FIG. 2) was used. The calculations were done taking the wavelength of exposure light provided by this Hg lamp as that of g-line, which was 436 nm in vacuum. Also, regarding the opening pattern 103, the calculations were done with respect to an example wherein the pattern comprised slits (small openings) having repetition of a number N. Each slit had an opening width 40 nm and a pitch (distance between centers of two adjoining slits) of p nm, as well as an opening length being sufficiently long as compared with the opening width.

Analysis was carried out while changing the pitch p from 100 nm to 80 nm and changing the slit number N from 2 to five.

As a result of the analysis, it has been found that the intensity distribution of near-field light in the photoresist in relation to the opening pattern 103 has the following features.

(1) In a pattern having an array of three or more slits, the intensity of near-field light just under the slit at an end is lower than the intensity of near-field light just under the central slit.

(2) In a pattern having an array of five slits, the intensities of near-field light at three central slits have small dispersion.

These phenomena can be considered and interpreted as being attributed to the following factors.

Under the conditions of various parameters such as pitch p described here, in the near-fields of plural slits, there is an effect of mutually strengthening the near-field light. In each slit, this effect acts on it from slits adjoining it. However, at a slit positioned at an end, this function acts on it only from one slit disposed at one side of the end slit and, therefore, the intensity of the near-field light thereof becomes relatively low.

Here, the mutually strengthening effect of near-field light may be taken as a result of a phenomenon that light beams passed through adjacent slits propagate in the photoresist or along a mask/resist interface (interface between the photomask and the photoresist).

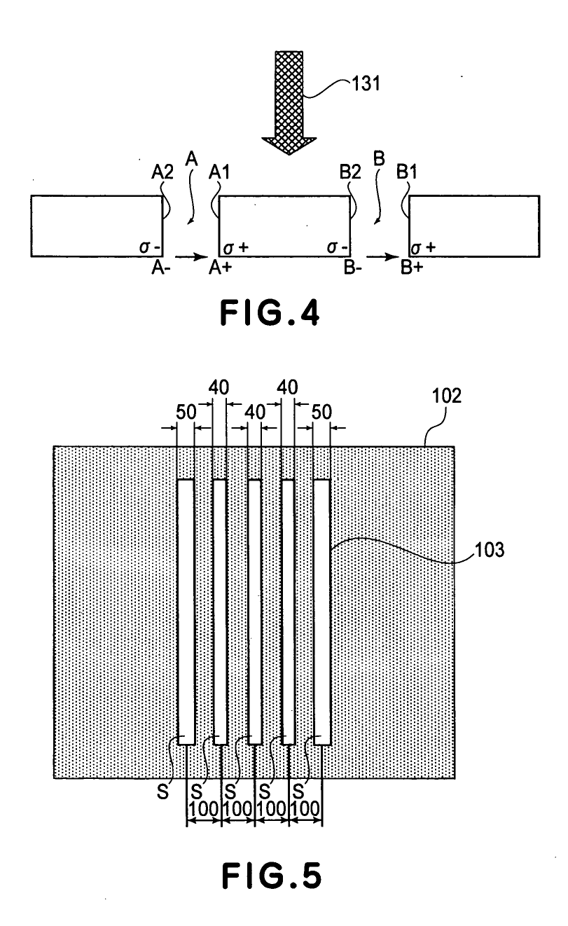

Now, a case shown in FIG. 4 is considered, wherein, onto slits A and B as small openings, a plane wave (exposure light 131) of frequency ω having an electric field vector orthogonal to the lengthwise direction of the slits A and B is incident. Specifically, a moment whereat a rightward electric field at the exit side (lower side in FIG. 4) of the slit A is largest is considered here. At a point A+ which is at the lower end of the right-hand side wall A1 of the slit A, induced electric charges take a largest value σ+. On the other hand, at a point A− which is at the lower end of the left-hand side wall A2 of the slit, induced electric charges take a maximum negative value σ−. As a result, the direction of electric field within the resist adjacent the photomask 100 is upward in the vicinity point A+ and it is downward in the vicinity of point A−. Because of being exited in plan waves, the situation is similar also in regard to the slit B. Namely, adjacent a point B+ which is at the lower end of the right-hand side wall B1 of the slit B, an upward electric field is being produced, while adjacent a point B− which is at the lower end of the left-hand side wall B2 of the slit B, a downward electric field is being produced.

The upward and downward electric fields produced within the photoresist are bonded with the surface plasmon polariton at the mask/resist interface, and they are turned into light that propagates along this interface. It would be understood that, since the vibration of frequency ω at point B− and the vibration of frequency ω at pint A+ have a phase difference of 180 degrees, if the distance between point B− and point A+ is a half (λ/2) of the surface plasmon polariton wavelength λ, the surface plasmon polariton exited by the induced electric charges at point B− turns into vibration of the same phase as the electromagnetic field around point A+, and thus the light intensity of near field is strengthened thereby. Also, it would be readily understood that, in order to enlarge the near-field light intensity in accordance with the principle described above, the distance between point B− and point A+ should be made larger than λ/4 and smaller than λx(¾).

On the other hand, in a region where the pitch p is 100 nm and under, the light itself that passes a slit produces a surface plasmon polariton mode bonded with adjacent slits, and it passes through the slit array. In this case, regarding the plasmon polariton mode at the outermost slit to light-blocking-film interface at an end slit, since there is no mate to be bonded with at the opposite side of the light blocking film 102, the loss at the outward slit becomes relatively large.

In this case, through a different mechanism than what described earlier, but in phenomenon a similar result is obtained, and the intensity distribution of near field light from the end of the slit array becomes weak.

As described above, the intensity of near field lights produced by an array of slits having the same opening width and the size of corresponding latent image patterns are different. Also, the intensity of near-field light at an end slit is weak. Thus, when an opening pattern is designed, the designing can be made while taking into account this effect by which variation in intensity of near-field lights corresponding to the slits can be reduced and by which uniform near-field light intensity distributions and thus latent images of even size are obtainable.

More particularly, the size of slits may be corrected, specifically to enlarge the slit width at an end slit of the slit array where the near field light becomes low. This makes even the intensity distributions of near-field lights produced in the photoresist.

An example of such correction, that is, an example of a photomask to which the present invention is applied, will be explained with reference to FIG. 5.

The photomask was designed under the following conditions. Namely, the mask base material 101 was made of SiN having a refractive index 1.9, and as the light blocking film 102, a Cr film of a thickness of 50 nm was formed on the surface of the mask base material 101. Then, a plurality of slits (small openings) were formed in the light blocking film 102. The photomask 100 thus produced was brought into intimate contact with a photoresist of 200 nm thickness upon an Si substrate. As regards the wavelength of exposure light from an exposure light source, g-line of 436 nm in vacuum was used. The light blocking film 102 had an array of five slits S being arrayed in parallel to each other. The opening length of each slit S was 2,000 nm, and for all slits the pitch p of adjacent slits was 100 nm. Regarding the slit opening width, three inner slits S had a width 40 nm while two outermost slits S had a width 50 nm. Namely, as regards correction for uniforming the intensity distribution of near-field lights, in the example of FIG. 5, the opening width of only two slits which are positioned outermost is widened.

The light blocking film 102 having an opening pattern 103 being corrected as described above was attached to the exposure apparatus 110 (FIG. 2), and exposure was carried out. The result was that approximately even intensity distributions of near-field light were produced from those slits S.

### Embodiment 2

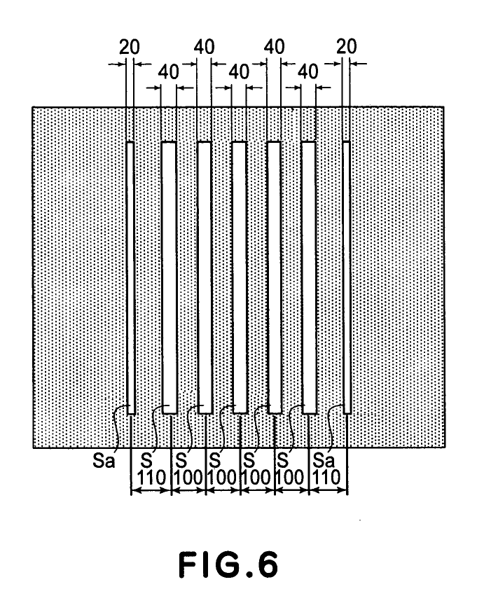

FIG. 6 shows another example of photomask 100 to which the present invention is applied. In this embodiment, an auxiliary small opening (correction opening) is additionally provided outside the slit array. It has been confirmed that, with such correction opening means, even at an outermost slit S, the strengthening effect from an adjacent outward opening as described above is available.

The design conditions were similar to those of FIG. 5, but in this example, outside an array of five slits S having a pitch p of 100 nm, an opening width 40 nm and an opening length of 2,000 nm, there were provided correction openings Sa having an opening width 20 nm and an opening length 2,000 nm. The distance between the center of the correction opening Sa and the center of a slit S, of the five slits S, adjoining the correction opening Sa, was made slightly larger than the pitch p (=100 nm) of the arrayed slits S, and it was equal to 110 nm.

In this case, since it is undesirable that an image is produced in the resist by the correction opening Sa itself, the size of the correction opening Sa should be made smaller than the opening width of the arrayed slit S.

Here, when a correction opening Sa having a smaller opening width than the slit S and providing only a weak near-field light distribution is going to be used, how it should be disposed will be explained.

As described hereinbefore, plasmon polariton from the correction opening Sa can strengthen the near-field intensity of an adjacent slit S provided that the distance from the correction opening to the adjacent slit S of the slit array is larger than λ/4 and smaller than (λx3)/4. Thus, when the correction opening Sa is disposed within this range, a correction effect of certain degree will be obtained.

For obtaining a best correction effect, however, optimum slit disposition will now be considered. To this end, it is now assumed that the opening width of the correction opening Sa is the same as the opening width of the arrayed slit S. If such correction opening Sa is disposed at the same pitch p as the interval of the arrayed slits S, the near-field light strengthening effect that an end slit S of the slit array receives from the correction opening Sa would become optimum. Namely, in that case the near-field light intensity distribution from the end slit S of the slit array would become approximately even to the near-field intensity from the other, inside slits S of the slit array. Here, the correction opening Sa to be used actually provides a lower near-field intensity than the slit S of the slit array, and thus the near-field strengthening effect would be smaller than the case described above.

Taking what described above into account, it would be desirable to shift the optimum disposition of the correction opening Sa to such place whereat a larger strengthening effect is obtainable than a case when the correction slit is disposed at the same interval as that of the arrayed slits S. Here, as described hereinbefore, the disposition by which a largest strengthening effect is that the interval is made equal to λ/2.

Actually, a light blocking film 102 having an opening pattern 103 being corrected in this manner was attached to the exposure apparatus 110 (FIG. 2), and exposure was carried out. The result was that approximately even intensity distributions of near-field light were produced from those slits.

### Embodiment 3

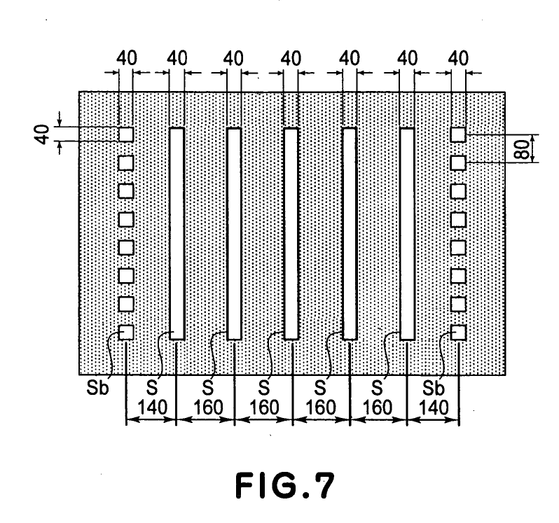

FIG. 7 shows a further example of photomask 100 to which the present invention is applied. In this example, additional openings Sb are provided in accordance with the same principle as has been described with reference to FIG. 6.

In this example, in place of using a slit of smaller opening width as a correction opening, the correction opening Sb consists of an array of very small openings each having the same opening width as that of the slit S of the slit array but having an opening length even smaller than a half of the wavelength.

The intensity distribution of near-field light provided by such small openings being smaller, in both of lateral size and longitudinal size, than the wavelength would be weak as compared with the intensity distribution of the near-field light to be provided by slit-like opening. Thus, with the method described above, a correction opening Sb that provides a weak strength than the opening of slit array S can be formed.

The correction openings Sb are disposed in accordance with similar disposition as used in the first embodiment of the present invention. Since in this embodiment the pitch p of the arrayed slits S is larger than the half wavelength of the surface plasmon polariton, the distance between the centers of the correction opening Sb and the adjacent slit S is made smaller than the pitch p of the slits S.

More specifically, there is an array of five slits S having pitch p of 160 nm, opening width of 40 nm, and opening length of 2,000 nm, and outside this slit array, there are very small openings of square shape with opening width 40 nm and opening length 40 nm, being disposed at a pitch of 80 nm, to provide the correction opening Sb. The distance between centers of the correction opening Sb and the adjacent slit S of the slit array is made smaller than the pitch p (=160 nm) of the slit array, and it is made equal to 140 nm.

By means of the correction openings Sb described above, the intensity distributions of near-field lights provided by the five arrayed slits S can be corrected into an approximately even distribution. Furthermore, since the near-field light provided by square correction openings Sb is weak as compared with the near-field light of the slits S, only a shallow resist pattern would be produced there and finally it would not be transferred to the substrate.

By using a photomask 100 having been described with reference to any one of the first to third embodiments, that is, by using a photomask being corrected specifically, a structure of a size of 100 nm and under can be produced very precisely.

Thus, in accordance with such microdevice manufacturing technology for a structure of a size of 100 nm or under, as described above, various specific devices can be produced. Examples are (1) a quantum dot laser device where the method is used for production of a structure in which GaAs quantum dots of 50 nm size are arrayed two-dimensionally at 50 nm intervals, (2) a sub wavelength element (SWS) structure having antireflection function where the method is used for production of a structure in which conical SiO₂ structures of 50 nm size are arrayed two-dimensionally at 50 nm intervals on a SiO₂ substrate, (3) a photonic crystal optics device or plasmon optical device where the method is used for production of a structure in which structures of 100 nm size, made of GaN or metal, are arrayed two-dimensionally and periodically at 100 nm intervals, (4) a biosensor or a micro-total analyzer system (μTAS) based on local plasmon resonance (LPR) or surface enhancement Raman spectrum (SERS) where the method is used for production of a structure in which Au fine particles of 50 nm size are arrayed two-dimensionally upon a plastic substrate at 50 nm intervals, (5) a nano-electromechanical system (NEMS) device such as SPM probe, for example, where the method is used for production of a radical structure of 50 nm size or under, to be used in a scanning probe microscope (SPM) such as a near-field optical microscope, an atomic force microscope, and a tunnel microscope, and the like.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2004-194819 filed Jun. 30, 2004, for which is hereby incorporated by reference.

What is claimed is:

1. A photomask for near-field exposure, comprising:
a light blocking film having a group of small openings being arrayed and each having an opening width not greater than a wavelength of exposure light,
wherein a shape and/or disposition of the small-opening group is set so that near-field light escaping from the small openings in response to projection of exposure light to the small openings has approximately even light intensity distributions.

2. A photomask according to claim 1, wherein the small openings are arrayed approximately equidistantly with respect to a direction of the opening width.

3. A photomask according to claim 2, wherein, of the small openings, a small opening disposed at an end portion has an opening width larger than the opening width of the other small openings so that the intensity distribution of near-field light of that small opening becomes approximately even with the other small openings.

4. A photomask according to claim 2, further comprising a correction opening provided outside a small opening of the group of small openings which is disposed at an end portion, the correction opening being arranged so that the intensity distribution of near-field light of that small opening becomes approximately even with the other small openings.

5. A photomask according to claim 4, wherein a distance d from the small opening disposed at the end portion to the correction opening, respect to a wavelength λ of plasmon polariton to be excited at an interface between the light blocking film and a photoresist being in contact with the light blocking film, is in a range from λ/4 to λx(¾).

6. A photomask according to claim 5, wherein the correction opening has an opening width smaller than the opening width of the small openings.

7. A photomask according to claim 5, wherein the distance d from the small opening at the end portion to the correction opening, with respect to a pitch p of adjacent small openings and the wavelength λ of the plasmon polariton, is between p and λ/2 in both of a case λ/2≦P and a case P≦λ/2.

8. A near-field exposure method, comprising:
preparing a photomask as recited in claim 1;
bringing the photomask into close contact with a substrate to be exposed, having a photoresist formed thereon;
irradiating the photomask with exposure light to produce an optical latent image in the photoresist,
wherein, where a correction opening is provided, the amount of exposure light irradiation is determined so that an exposure amount of near-field light at the correction opening becomes small and substantially no image is formed thereby.

9. A method according to claim 8, further comprising a developing process based on a dual-layer resist method in which the photoresist comprises an upper layer resist and a lower layer resist, wherein at a position on the photoresist corresponding to a small opening of the photomask, after the development process a resist pattern that reaches a bottom of the upper layer resist is produced, while at a position corresponding to the correction opening, after the development process a resist pattern that does not reach the bottom of the upper layer resist is produced.

10. A device manufacturing method including a process for producing a device by use of a near-field exposure method as recited in claim 8 or 9.
